(19) United States
(12) Patent Application Publication
(10) Pub. No.: US 2007/0290210 A1
(43) Pub. Date: Dec. 20, 2007

(54) SEMICONDUCTOR DEVICE AND METHOD OF FABRICATING A LTPS FILM

(76) Inventors: Chih-Hsiung Chang, Tai-Chung Hsien (TW); Yi-Wei Chen, I-Lan Hsien (TW); Ming-Wei Sun, Kao-Hsiung City (TW)

Correspondence Address: NORTH AMERICA INTELLECTUAL PROPERTY CORPORATION, P.O. BOX 506, MERRIFIELD, VA, 22116, US

(21) Appl. No.: 11/776,561

(22) Filed: Jul. 12, 2007

Related U.S. Application Data
(62) Division of application No. 10/907,436, filed on Mar. 31, 2005.

(30) Foreign Application Priority Data
Sep. 23, 2004 (TW) 093128886

(51) Int. Cl. H01L 29/04; H01L 21/20

(52) U.S. Cl. 257/75; 438/479; 257/E29.083; 257/E21.09; 257/E21.29; 257/E21.293; 257/E21.347; 257/E29.003

(57) ABSTRACT

A semiconductor device and a method of fabricating a low-temperature polysilicon film are provided. An amorphous silicon film is formed over a substrate. An insulating layer and a laser absorption layer are formed over the amorphous silicon film. A photolithographic and etching process is performed to remove portions of the laser absorption layer and the insulating layer to expose portions of the amorphous silicon film. A laser crystallization process is utilized to convert the amorphous silicon film into a polysilicon film.

### CROSS REFERENCE TO RELATED APPLICATIONS

This application is a divisional of application Ser. No. 10/907,436 filed Mar. 31, 2005.

### BACKGROUND OF THE INVENTION

1. Field of the Invention

The present invention relates to a semiconductor device and a method of fabricating a low-temperature polysilicon (LTPS) film, and more particularly, to a semiconductor device and a method of fabricating a LTPS film utilizing lateral grain growth.

2. Description of the Prior Art

In the process of fabricating thin-film transistor liquid crystal displays (TFT LCDs), glass deforms when exposed to temperature above 600° C, and the deposition temperature of a polysilicon film is required to between 575-650° C. In order to avoid deformation of the glass substrate at the high temperature for depositing the poly silicon film, a method of crystallizing an amorphous silicon layer has been gradually adopted in the present fabrication of LTPS films in TFT LCDs.

A conventional LTPS film is fabricated on an insulating substrate, and the insulating substrate is made of materials pervious to light, such as a glass substrate, a quartz substrate, or a plastic substrate. A conventional method for forming the LTPS film includes forming an amorphous silicon film on the insulating substrate, and then performing an excimer laser annealing (ELA) process to make the amorphous silicon film crystallize into a polysilicon film. In the process of ELA, the amorphous silicon film melts and crystallizes quickly through the absorption of laser to form the polysilicon film. Since the fast absorption of the short pulse duration laser merely affects the surface of the amorphous silicon film, the insulating substrate is not affected by laser and can be kept at low temperature.

Because the quality of the amorphous silicon film has great influence on the characteristics of the polysilicon TFT subsequently formed, parameters in the deposition process of the amorphous silicon film should be carefully controlled to form the amorphous silicon film with low hydrogen content, high uniformity of film thickness, and low surface roughness. The polysilicon film formed from the crystallization of the amorphous silicon layer serves as a semiconductor layer in the TFT to define a source, a drain, and a channel region between the source and the drain. The quality of the polysilicon film has direct influence on the electrical performance of the semiconductor device. For example, the grain size of the polysilicon film is an important factor that can influence the quality of the polysilicon film.

In order to increase the grain size of the polysilicon film, Taiwan patent TW 485496, which corresponds to U.S. Pat. No. 6,555,449 B1, provides a sequential lateral solidification (SLS) process. The SLS process uses a mask in a laser optical system to shield a portion of laser. The portions of amorphous silicon film not irradiated by laser keep in a solid state, and the portions of amorphous silicon film irradiated by laser melt into a liquid state. Using the temperature gradient between the two areas of the amorphous silicon film, the direction of the grain growth can be controlled. Although this method produces grain sizes much bigger than the conventional grain sizes, it can't control the numbers of grains and grain boundaries in the channel region of the device. For example, some transistors in a TFT LCD may have main grain boundaries in the channel regions while some other transistors in the TFT LCD may have no main grain boundaries in the channel regions. As a result, noticeable difference of electrical characteristics in the transistor is produced. To improve the uniformity of electrical characteristics of the transistor, the conventional solution is to reduce the utilizable area of the polysilicon film and compromise on the shapes and positions of the transistors.

Taiwan patent TW 452892, which corresponds to U.S. Pat. No. 6,432,758 B1, provides a method of controlling the thickness of amorphous silicon film to produce a temperature gradient in the amorphous silicon film. According to TW 452892, a photolithographic and etching process is utilized to control the thickness of the amorphous silicon film and make the amorphous silicon film have different thicknesses at different locations, so as to control the growth direction of silicon grains. The method controls the silicon grains to uniformly grow along a lateral direction, however, damage to the uniformity is caused during the etching process and different thicknesses of the amorphous silicon film at different locations will affect the activation process.

In addition, Taiwan patent TW 466569 also provides a method of forming a reflective metal layer on the surface of amorphous silicon film to produce a temperature gradient in the amorphous silicon film. According to TW 466569, a metal pattern is coated on the amorphous silicon film over a substrate, and the substrate is heated to keep the substrate at a certain temperature before the ELA process is performed.

To prevent the limitations as above-mentioned from obstructing applications to LTPS, how to effectively increase the grain sizes and control the orientation of grains to improve the electrical performance of LTPS LCDs has become an important issue.

### SUMMARY OF THE INVENTION

An object of the present invention is to provide a semiconductor device and a method of fabricating an LTPS film to control the numbers of grains and grain boundaries in a channel region defined in the LTPS film and thus improve the electrical performance of the semiconductor device.

According to one embodiment of the present invention, an amorphous silicon film is formed over a substrate. An insulating layer and a laser absorption layer are formed over the amorphous silicon film. Following that, a photolithographic and etching process is performed to remove portions of the laser absorption layer and the insulating layer to expose portions of the amorphous silicon film. A laser crystallization process is then utilized to convert the amorphous silicon film into a poly-silicon film.

It is an advantage of the present invention that the laser absorption layer and the insulating layer are utilized to cover portions of the amorphous silicon film and make the covered portions of the amorphous silicon film get rid of laser irradiation. A temperature gradient occurs between the portions of the amorphous silicon film without laser irradiation and the portions of the amorphous silicon film with laser irradiation. This temperature gradient induces a lateral growth of silicon grains from the region without laser irradiation toward the region with laser irradiation. Accordingly, the present invention controls the numbers of grains and grain boundaries in the channel region via the pattern definition of the laser absorption layer and the insulating layer. Since it is achievable to form bigger grain sizes with only one grain boundary in the channel region, the carrier mobility and uniformity of TFTs can be improved, and a better electrical performance of the semiconductor device can be provided.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1 and 2 are schematic diagrams of a method of fabricating an LTPS film according to the present invention;

FIG. 3 illustrates a temperature gradient at an amorphous silicon film according to the present invention;

FIG. 4 is a scanning electron microscopy (SEM) photograph of silicon grains in a polysilicon film according to the present invention;

FIG. 5 illustrates laser absorption conditions of laser absorption layers under laser irradiation with different laser wavelengths; and

FIG. 6 is a schematic diagram of a semiconductor device according to the present invention.

### DETAILED DESCRIPTION

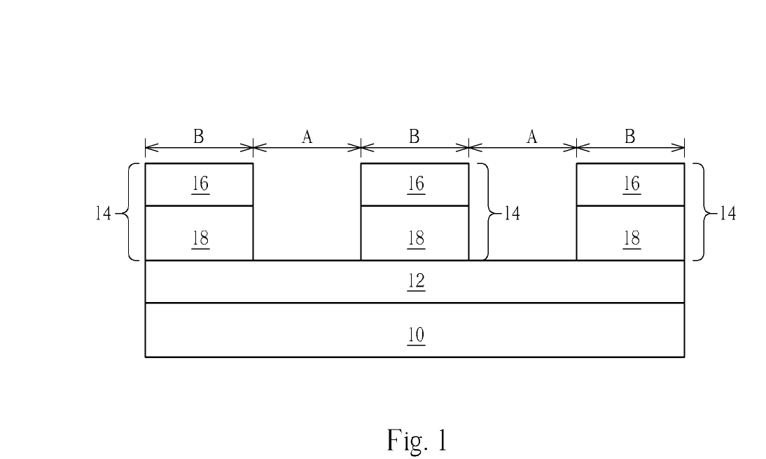

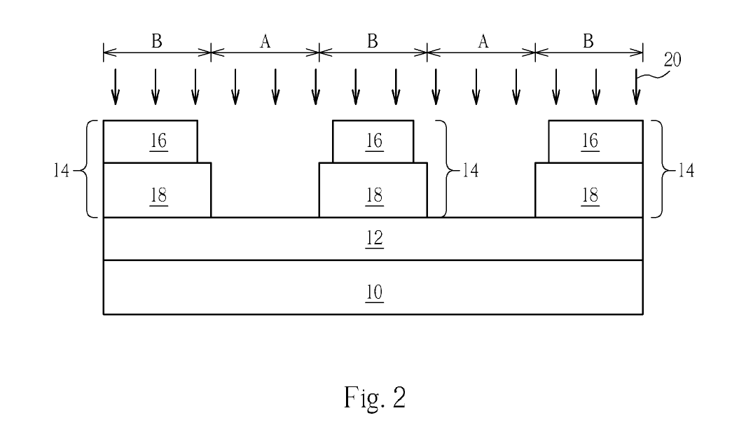

Referring to FIGS. 1 and 2, FIGS. 1 and 2 are schematic diagrams of a method of fabricating an LTPS film according to the present invention. As shown in FIG. 1, a substrate 10, such as a glass substrate, a quartz substrate, or a plastic substrate, is provided. An amorphous silicon film 12 is formed on the substrate 10, and a laser isolation pattern 14, which is composed of a laser absorption layer 16 and an insulating layer 18, is formed to cover portions of the amorphous silicon film 12. For example, a plasma enhanced chemical vapor deposition (PECVD) is used to continuously deposit the amorphous silicon film 12, the insulating layer 18 and the laser absorption layer 16 on the substrate 10. At least one channel region A and at least one non-channel region B surrounding the channel region A are defined in the amorphous silicon film 12. The laser absorption layer 16 can be formed of at least one material selected from amorphous silicon, polysilicon, metal oxide (including TiO₂, Ta₂O₅, Al₂O₃, etc.), semiconductor materials (including SiGe, SiAs, GeAs, etc.) and refractory metal (including Ti, Al, Pt, etc.). Preferably, the laser absorption layer 16 is formed of non-metal, such as amorphous silicon, polysilicon, and semiconductor materials, so as to prevent metallic pollution in the channel region A. The laser absorption layer 16 can be a single material layer or a composite layer including a plurality of single-material layers. When the laser absorption layer 16 is the single material layer, a preferred thickness of the laser absorption layer 16 is substantially about 500 Å, but the other thickness may be used. When the laser absorption layer 16 includes a plurality of single-material layers, each of the single-material layers may have a preferred thickness of substantially about 500 Å, but the other thickness may be used. The insulating layer 18 is formed of materials capable of providing superior insulation, for example, the insulating layer 18 can be a single material layer or a composite layer of silicon oxide (SiOₓ), silicon nitride (Si_{z}Nₓ), silicon oxynitride (SiO_{y}Nₓ), low-k materials (including block diamond, fluorinated silicate glass (FSG), phosphorus-doped silicon dioxide glass (PSG), silicon carbon (SiC), etc.), or metal oxide (including TiO₂, Ta₂O₅, Al₂O₃, etc.). The insulating layer 18 absorbs laser energy and prevents heat transmission from the laser absorption layer 16 to the amorphous silicon film 12 underlying the insulating layer 18. A preferred thickness of the insulating layer 18 is suggested as about 1500 Å.

After the amorphous silicon film 12, the insulating layer 18, and the laser absorption layer 16 are formed on the substrate 10, a de-hydrogen process is performed at an furnace with a temperature higher than 400° C. to reduce the hydrogen content in the amorphous silicon film 12. Following that, a photolithographic and etching process is performed to define the patterns of the laser absorption layer 16 and the insulating layer 18. For example, the portions of the laser absorption layer 16 and the insulating layer 18 covering the channel region A are removed, and the portions of the laser absorption layer 16 and the insulating layer 18 covering the non-channel region B are remained to form the laser isolation pattern 14. The laser isolation pattern 14 prevents laser irradiation and laser energy absorption of the portions of the amorphous silicon film 12 surrounding the channel region A.

As shown in FIG. 2, a laser crystallization process is performed, for example, excimer laser beams 20 are utilized to irradiate the amorphous silicon film 12 and to convert the amorphous silicon film 12 into a polysilicon film. During the laser crystallization process, the laser absorption layer 16 shrinks because of the irradiation by the laser beams, the portions of the amorphous silicon film 12 covered by the laser isolation pattern 14 (i.e. the portions of the amorphous silicon film 12 within the non-channel region B) are not irradiated by the laser beams nor absorb the laser energy, and the portions of the amorphous silicon film 12 not covered by the laser isolation pattern 14 (i.e. the portions of the amorphous silicon film 12 within the channel region A) are directly exposed to laser.

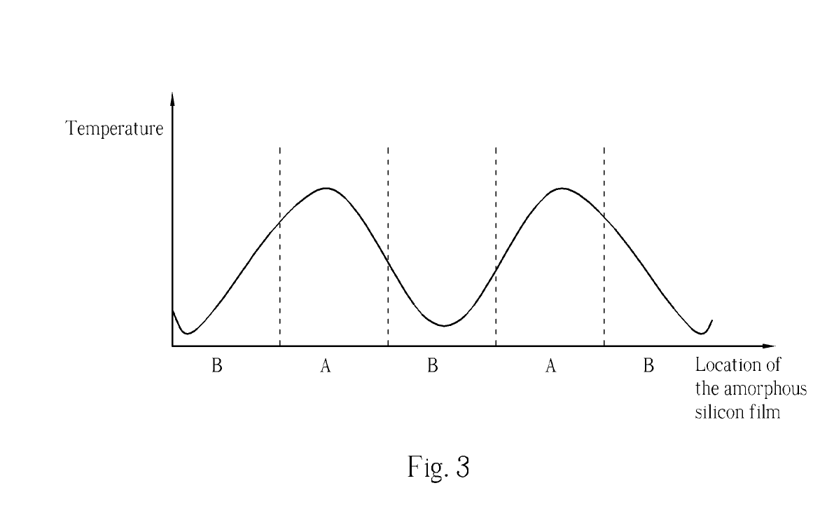

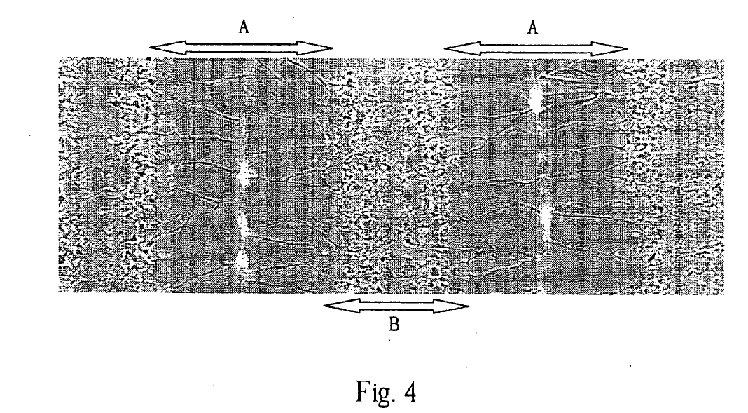

Referring to FIG. 3, FIG. 3 illustrates a temperature gradient at a surface of an amorphous silicon film according to the present invention. As shown in FIG. 3, a temperature gradient distribution is formed in the amorphous silicon film 12 according to the isolation effect provided by the laser isolation pattern 14. For example, a high-temperature region is formed in the channel region A, a low-temperature region is formed in the non-channel region B, and thus a lateral grain growth of the amorphous silicon film 12 is produced from the low-temperature region to the high-temperature region. Referring to FIG. 4, FIG. 4 is a scanning electron microscopy (SEM) photograph of silicon grains in a polysilicon film after the completion of the laser crystallization process and the removal of the laser isolation pattern 14. As shown in FIG. 4, the portions of the polysilicon film within the channel region A have bigger grains because of the absorption of laser energy, and only one grain boundary is formed within the channel region A. On the contrary, the portions of the polysilicon film within the non-channel region B have smaller grains and lots of grain boundaries because of the lack of energy. Since the present invention provides bigger grains and single grain boundary within the channel region A, the carrier mobility and uniformity in TFTs can be improved and better electrical performance of the device can be obtained.

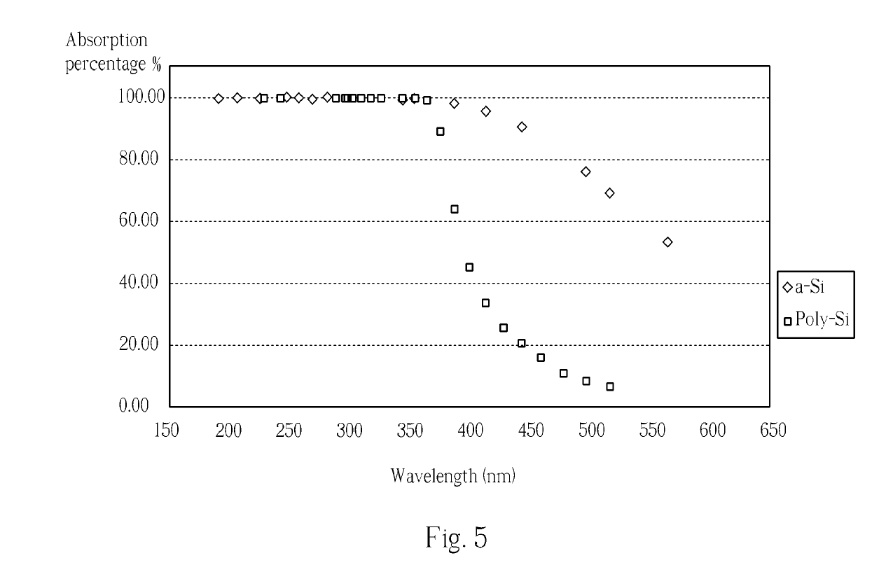

Referring to FIG. 5, FIG. 5 illustrates laser absorption conditions of laser absorption layers under laser irradiation with different laser wavelengths. A thickness of a laser absorption layer is about 500 Å to do the exemplification of the present invention. As shown in FIG. 5, when the laser absorption layer is made of amorphous silicon (designated by the symbol ⋄) or made of polysilicon (designated by the symbol □), it can almost completely absorb the laser with a wavelength under 350 nm. Therefore, amorphous silicon or polysilicon is suitable to form the laser absorption layer for absorbing excimer laser beams, such as KrF laser (with a wavelength of 248 nm) and ArF laser (with a wavelength of 193.3 nm). The present invention is not limited to using amorphous silicon or polysilicon to form the laser absorption layer, however, other laser absorption materials can also be used according to the design choices of electrical characteristics of TFTs, laser types or production costs to achieve ideal laser absorption results.

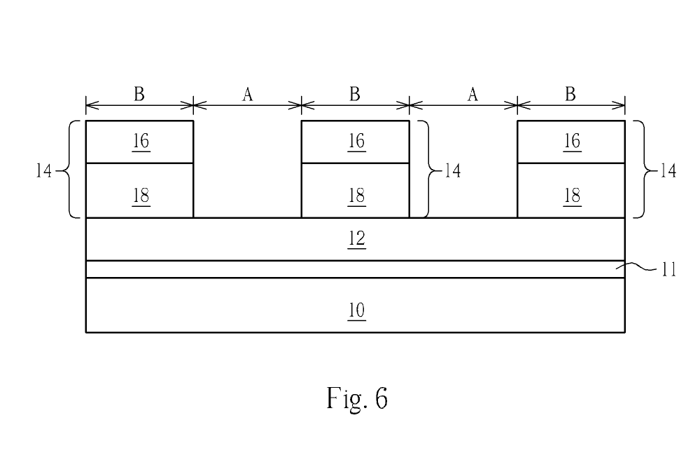

In other embodiments of the present invention, a buffer layer can be optionally formed between the amorphous silicon film and the substrate to prevent thermal diffusion between the amorphous silicon film and the substrate. Referring to FIG. 6, FIG. 6 is a schematic diagram of a semiconductor device having a buffer layer 11. Practically, The buffer layer 11 can be positioned either between the amorphous silicon film 12 and the substrate 10 or between the amorphous silicon film 12 and the laser isolation pattern 14. While the buffer layer 11 being interposed between the amorphous silicon film 12 and the laser isolation pattern 14, the edges of the buffer layer 11 can be aligned to the edges of the laser isolation pattern 14, so as to expose the portions of the amorphous silicon film 12. In FIG. 6, the same reference numerals as those shown in FIG. 1 refer to the same elements, and the same process steps as those described in FIG. 2 are applicable to the device shown in FIG. 6. After the fabrication of the LTPS film and the removal of the laser isolation pattern, the present invention further includes a TFT process, which includes doping the LTPS film, forming a gate insulating layer, a gate (a first metal layer), an interlayer dielectric layer, a source/drain conducting wire (a second metal layer), a passivation layer, and an ITO transparent conductive layer, so as to complete an LTPS TFT.

The present invention is characterized by forming the laser isolation pattern, including the laser absorption layer and the insulating layer, on the amorphous silicon film before the laser crystallization process. As a result, the temperature gradient occurs at the amorphous silicon film to control the sizes and orientation of the silicon grains. In addition, the present invention utilizes the photolithographic and etching process to form the laser isolation pattern over the portions of the amorphous silicon film surrounding the channel region. The shape, the thickness, and the location of the laser isolation pattern can be easily adjusted by changing the parameters of the photolithographic and etching process to obtain an ideal laser absorption result. In this case, the grain size and the grain boundary number formed by the laser crystallization process can be effectively controlled, and bigger grains and less grain boundary number can be formed within the channel region in the LTPS TFT.

In contrast to the prior art method of fabricating the LTPS film, the present invention uses the laser absorption layer and the insulating layer to control local grain growth. Accordingly, the present invention controls the numbers of grain and grain boundaries in the channel region via the pattern definition of the laser absorption layer and the insulating layer. Since it is achievable to form bigger grain sizes with only one grain boundary in the channel region, the carrier mobility and uniformity of TFTs can be improved, and a better electrical performance of the semiconductor device can be provided.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method of fabricating a low-temperature polysilicon film, comprising:
providing a substrate;
forming an amorphous silicon film over the substrate;
forming a laser isolation pattern over the amorphous silicon film to expose portions of the amorphous silicon film and to define at least one channel region in the amorphous silicon film; and
performing a laser crystallization process to convert the amorphous silicon film into a polysilicon film;
wherein the laser isolation pattern prevents the portions of the amorphous silicon film adjacent to the channel region from being irradiated by laser or absorbing laser energy, so as to generate a temperature gradient at the surface of the amorphous silicon film.

2. The method of claim 1, wherein the laser isolation pattern comprises a laser absorption layer or an insulating layer.

3. The method of claim 2, wherein the laser absorption layer comprises a material selected from the group consisting of amorphous silicon, polysilicon, metal oxide, semiconductor materials, refractory metal, and combination thereof.

4. The method of claim 2, wherein the insulating layer comprises a material selected from the group consisting of silicon oxide, silicon nitride, silicon oxynitride, low-k materials, metal oxide, and combination thereof.

5. The method of claim 1, further comprising forming a buffer layer between the amorphous silicon film and the substrate.

6. The method of claim 1, wherein the temperature gradient at the surface of the amorphous silicon film characterizes in that the temperature of the portions of the amorphous silicon film covered by the laser isolation pattern is lower than the temperature of the portions of the amorphous silicon film not covered by the laser isolation pattern.

7. A semiconductor device, comprising a polysilicon film formed by the method of claim 1.

8. A semiconductor device, comprising:
a substrate;
an amorphous silicon film formed over the substrate; and
a laser isolation pattern, formed over the amorphous silicon film, adapted to expose portions of the amorphous silicon film and to define at least a channel region in the amorphous silicon film, wherein the laser isolation pattern is adapted to prevent the portions of the amorphous silicon film adjacent to the channel region from being irradiated by laser or absorbing laser energy, so as to generate a temperature gradient at the surface of the amorphous silicon film.

9. The semiconductor device of claim 8, wherein the laser isolation pattern comprises a laser absorption layer or an insulating layer.

10. The semiconductor device of claim 9, wherein the laser absorption layer comprises a material selected from the group consisting of amorphous silicon, polysilicon, metal oxide, semiconductor materials, refractory metal, and combination thereof.

11. The semiconductor device of claim 9, wherein the insulating layer comprises a material selected from the group consisting of silicon oxide, silicon nitride, silicon oxynitride, low-k materials, metal oxide, and combination thereof.

12. The semiconductor device of claim 8, further comprising a buffer layer formed between the amorphous silicon film and the substrate.

13. The semiconductor device of claim 8, wherein the temperature gradient at the surface of the amorphous silicon film characterizes in that the temperature of the portions of the amorphous silicon film covered by the laser isolation pattern is lower than the temperature of the portions of the amorphous silicon film not covered by the laser isolation pattern.
